(19) United States
(12) Patent Application Publication
(10) Pub. No.: US 2021/0366887 A1
(43) Pub. Date: Nov. 25, 2021

(54) METHOD FOR EFFICIENT MANUFACTURE OF DISPLAY PANEL

(71) Applicant: Century Technology (Shenzhen) Corporation Limited, Shenzhen (CN)

(72) Inventors: PO-LIANG CHEN, New Taipei (TW); YUNG-FU LIN, New Taipei (TW)

(21) Appl. No.: 17/026,627

(22) Filed: Sep. 21, 2020

(30) Foreign Application Priority Data
May 19, 2020 (CN) 202010426471.4

(51) Int. Cl. H01L 25/16; H01L 33/52; H01L 33/62; H01L 33/50; H01L 33/00

(52) U.S. Cl. CPC H01L 25/167; H01L 33/52; H01L 33/62; H01L 33/06; H01L 33/007; H01L 33/0093; H01L 33/505

(57) ABSTRACT

A method for efficient manufacture of a color or monochrome display panel by an masse transfer of a large number of light emitting elements includes providing crystal blocks, providing a driving substrate, transferring the crystal blocks to the driving substrate, patterning the crystal blocks, and applying wavelength-converting elements to each light source, for a monochrome or color display device.

### FIELD

The subject matter herein generally relates to displays and particularly relates to a method for making a display panel.

### BACKGROUND

The sizes of light emitting elements such as light emitting diodes (LEDs) are always tending towards smaller size, as a result, efficiently transferring a large number of light emitting elements to a target substrate is challenging.

Therefore, there is room for improvement in the art.

### BRIEF DESCRIPTION OF THE DRAWINGS

Implementations of the present disclosure will now be described, by way of embodiment, with reference to the attached figures.

FIG. 1 is a flow chart of a method for making a display panel according to an embodiment.

FIG. 2 is a top view illustrating crystal blocks in Block S1 of the method disclosed in FIG. 1.

FIG. 3 is a cross-sectional view along line of FIG. 2.

FIG. 4 is a top view illustrating a driving substrate in Block S2 of the method.

FIG. 5 is a cross-sectional view along line V-V of FIG. 4.

FIG. 6 is a top view illustrating the crystal blocks and the driving substrate in Block S3 of the method.

FIG. 7 is a cross-sectional view along line VII-VII of FIG. 6.

FIG. 8 is a cross-sectional view illustrating the patterning of crystal blocks into light emitting elements in Block S4 of the method.

FIG. 9 is a cross-sectional view of a display panel according to a first embodiment.

FIG. 10 is a cross-sectional view of a display panel according to a second embodiment.

### DETAILED DESCRIPTION

It will be appreciated that for simplicity and clarity of illustration, where appropriate, reference numerals have been repeated among the different figures to indicate corresponding or analogous elements. In addition, numerous specific details are set forth to provide a thorough understanding of the exemplary embodiments described herein. However, it will be understood by those of ordinary skill in the art that the exemplary embodiments described herein may be practiced without these specific details. In other instances, methods, procedures, and components have not been described in detail so as not to obscure the related relevant feature being described. Also, the description is not to be considered as limiting the scope of the exemplary embodiments described herein. The drawings are not necessarily to scale and the proportions of certain parts may be exaggerated to better illustrate details and features of the present disclosure.

The term “comprising” when utilized, means “including, but not necessarily limited to”; it specifically indicates open-ended inclusion or membership in the so-described combination, group, series, and the like. The disclosure is illustrated by way of example and not by way of limitation in the figures of the accompanying drawings in which like references indicate similar elements. It should be noted that references to “an” or “one” embodiment in this disclosure are not necessarily to the same embodiment, and such references can mean “at least one”.

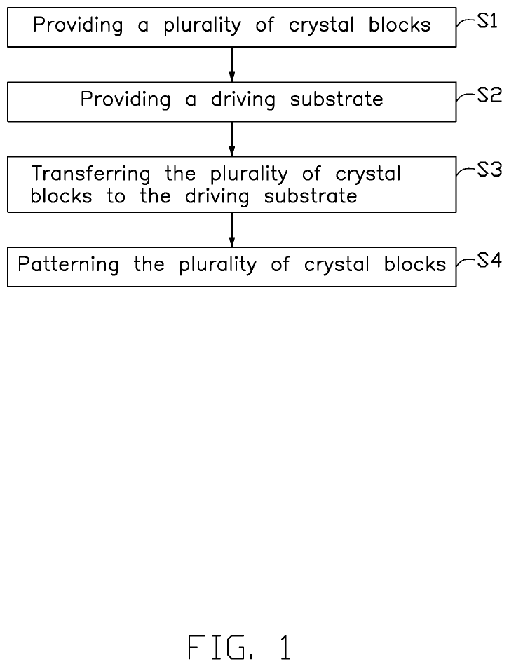

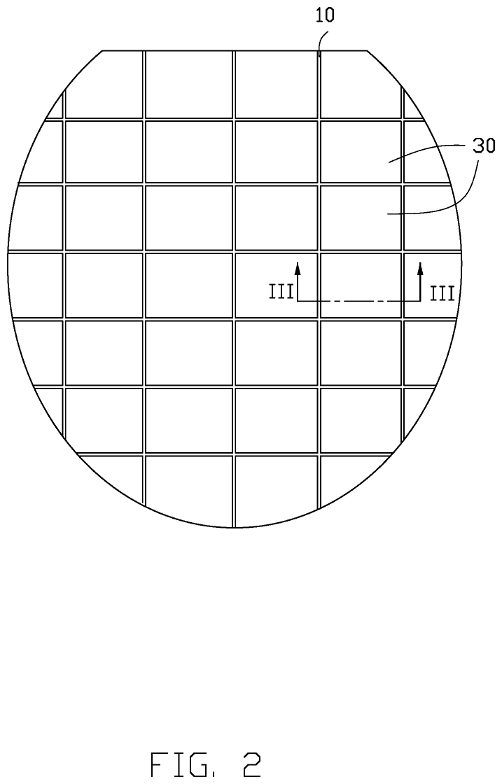

Referring to FIG. 1, a flow chart of a method for making a display panel is disclosed. The method is provided by way of embodiment, as there are a variety of ways to carry out the method. The method described below can be carried out using the configurations illustrated in FIGS. 2 through 10 for example, and various elements of these figures are referenced in explaining the method. Each block shown in FIG. 1 represents one or more processes, methods, or subroutines, carried out in the method. Additionally, the illustrated order of blocks is by example only and the order of the blocks can change. The method can begin at Block S1.

Block S1: a plurality of crystal blocks 30 is provided.

As shown in FIG. 2, the crystal blocks 30 are spaced apart from each other on a substrate 10. The substrate 10 may be a growth substrate of the crystal blocks 30, and a material of the substrate 10 may be sapphire, quartz, or the like.

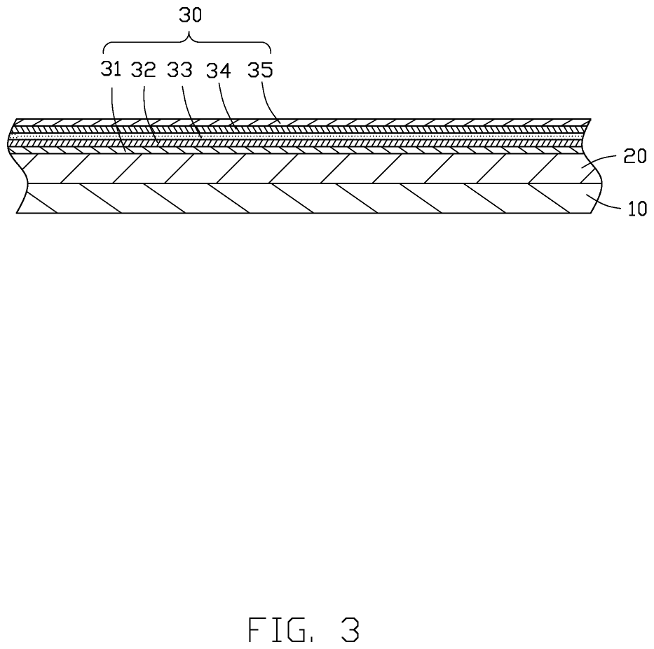

As shown in FIG. 3, the Block S1 further includes providing the substrate 10, forming a release layer 20 on the substrate 10, and forming the crystal blocks 30 to be spaced apart from each other on a surface of the release layer 20 away from the substrate 10. Each of the crystal blocks 30 includes a first electrode layer 31, a P-type doped phosphor layer 34, an active layer 33, an N-type doped phosphor layer 32, and a second electrode layer 35 arranged in that order.

In one embodiment, the release layer 20 may be an adhesive layer of a type of colloid that decomposes and loses its viscosity under laser irradiation, ultraviolet irradiation, or heating. The P-type doped phosphor layer 34 is, for example, a P-type gallium nitride layer. The active layer 33 is, for example, a multiple quantum well layer. The N-type doped phosphor layer 32 is, for example, an N-type gallium nitride layer.

Block S2: a driving substrate 50 is provided.

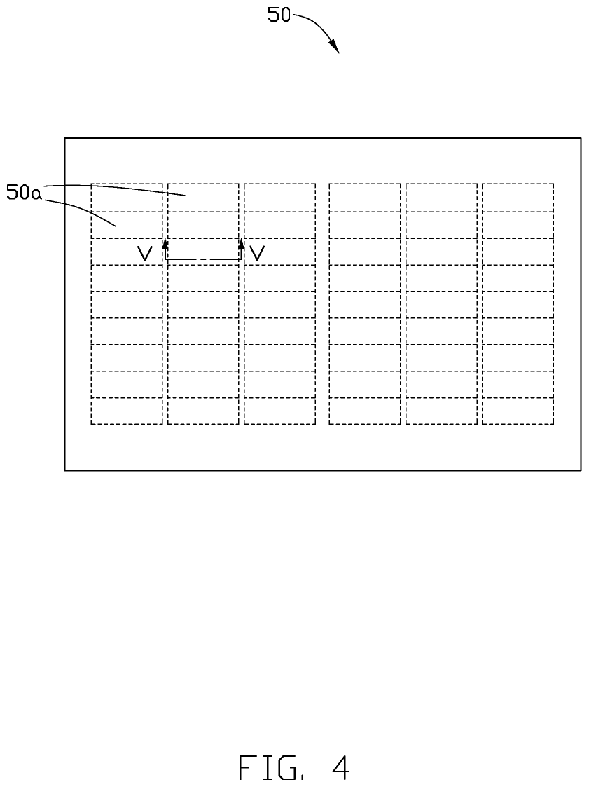

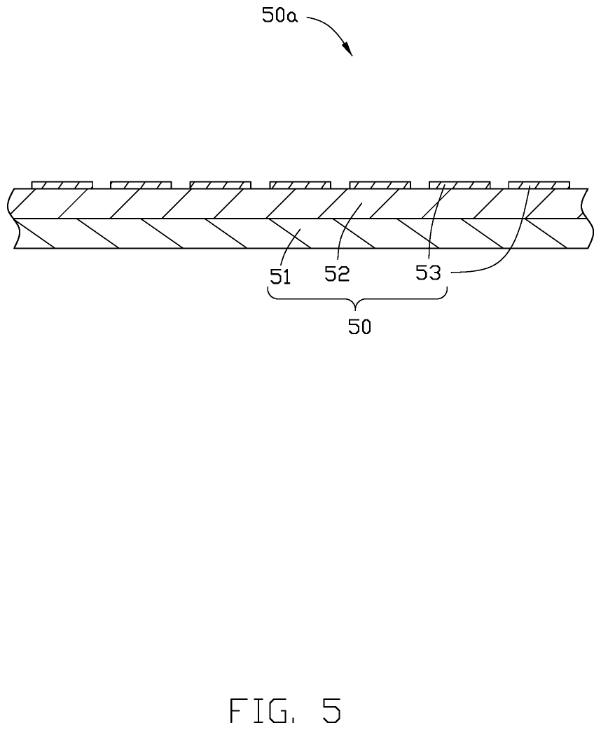

As shown in FIG. 4, the driving substrate 50 defines a plurality of receiving areas 50a. Each of the receiving areas 50a is configured for receiving one of the crystal blocks 30. As shown in FIG. 5, each of the receiving areas 50a defines a plurality of conductive blocks 53 spaced apart from each other.

In one embodiment, the driving substrate 50 is a thin film transistor substrate. The driving substrate 50 includes a base layer 51, a driving circuit layer 52 (e.g., a thin film transistor array layer) on the base layer 51 and the conductive blocks 53 one a side of the driving circuit layer 52 away from the base layer 51. Each of the conductive blocks 53 is electrically connected to the driving circuit layer 52.

In one embodiment, the base layer 51 may be made of a rigid material, such as glass, quartz, silicon wafer, or the like. In other embodiments, the base layer 51 may be made of a flexible material, such as polyimide (PI) or polyethylene terephthalate (PET).

Block S3: the crystal blocks 30 are transferred to the driving substrate 50.

In one embodiment, the release layer 20 is processed by laser irradiation, ultraviolet irradiation, or heating, so that each of the crystal blocks 30 is transferred to one of the receiving areas 50a.

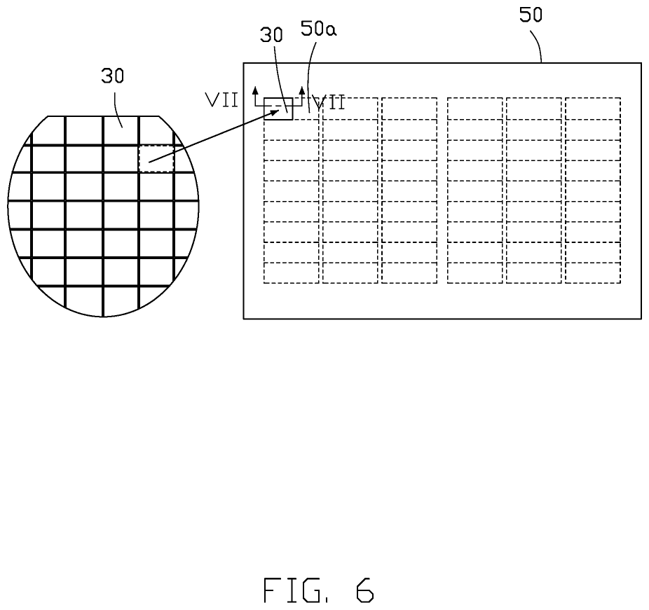

As shown in FIG. 6, in step S3, one of the crystal blocks 30 is transferred to one of the receiving areas 50a of the driving substrate 50 each time.

In one embodiment, the positioning and size of each receiving area 50a on the driving substrate 50 are compatible with the positioning and size of each crystal block 30 on the substrate 10. In step S3, more than one crystal block 30 can be transferred to the driving substrate 50 each time.

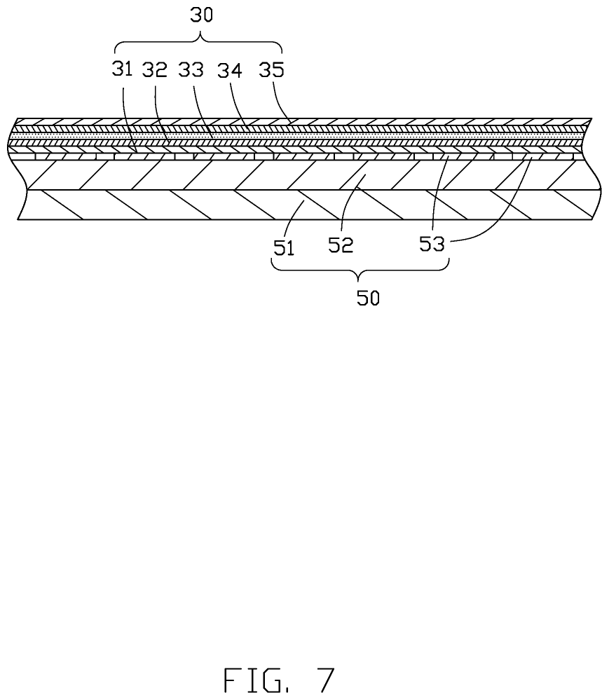

As shown in FIG. 7, after each of the crystal blocks 30 is transferred onto one receiving area 50a, the first electrode layer 31 covers all the conductive blocks 53 in the receiving area 50a. There is a gap between two adjacent conductive blocks 53.

Block S4: each of the crystal blocks 30 is patterned.

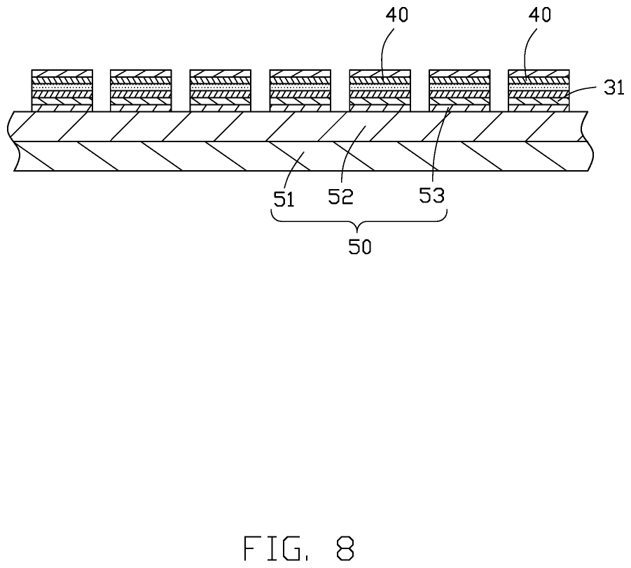

As shown in FIG. 8, the first electrode layer 31, the P-type doped phosphor layer 34, the active layer 33, the N-type doped phosphor layer 32, and the second electrode layer 35 are all patterned. Each of the crystal blocks 30 is patterned to form a plurality of spaced light emitting elements 40. Each of the light emitting elements 40 includes the patterned first electrode layer 31, the patterned P-type doped phosphor layer 34, the patterned active layer 33, the patterned N-type doped phosphor layer 32, and the patterned second electrode layer 35.

Each of the light emitting elements 40 is on one of the conductive blocks 53 and is electrically connected to the one of the conductive blocks 53 through the first electrode layer 31. That is, each of the light emitting elements 40 is electrically connected to the driving circuit layer 52 through one of the conductive blocks 53.

In one embodiment, the light emitting element 40 may be a conventional light emitting diode (LED), mini LED, or micro LED. “Micro LED” means LED with a grain size of fewer than 100 microns. The mini LED is also a sub-millimeter LED, its size is between conventional LED and micro LED. “Mini LED” generally means LED with a grain size of about 100 microns to 200 microns.

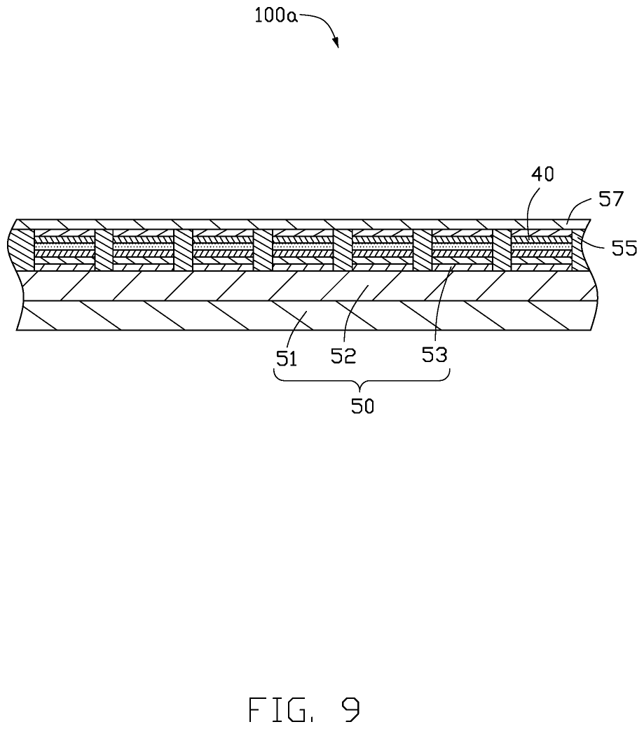

In one embodiment, after step S4, the method further includes forming an insulating block 55 between adjacent light emitting elements 40 and forming a cover 57 on a side of the light emitting element 40 away from the driving substrate 50. Thereby, a display panel 100a shown in FIG. 9 is obtained. The adjacent light emitting elements 40 are insulated and are spaced from each other by one of the insulating blocks 55. The cover 57 protects and seals the driving circuit layer 52 and the light emitting elements 40 from moisture and other contaminants.

In one embodiment, the light emitting elements 40 obtained by patterning the same crystal block 30 can emit light of one color. The patterning of light emitting elements 40 may also create elements 40 which emit light of different colors. For example, some crystal blocks 30 are patterned to form light emitting elements 40 emitting blue light, some crystal blocks 30 are patterned to form light emitting elements 40 emitting red light, and some crystal blocks 30 are patterned to form light emitting elements 40 emitting green light, and so on. Thereby, the display panel 100a can be a color display panel.

In other embodiments, all the crystal blocks 30 are patterned to form light emitting elements 40 emitting light of one color. For example, all the crystal blocks 30 can be patterned to form light emitting elements 40 which emit red light, or all emitting green light, or all emitting blue light, and so on. Thereby, the display panel 100a can be a monochrome display panel.

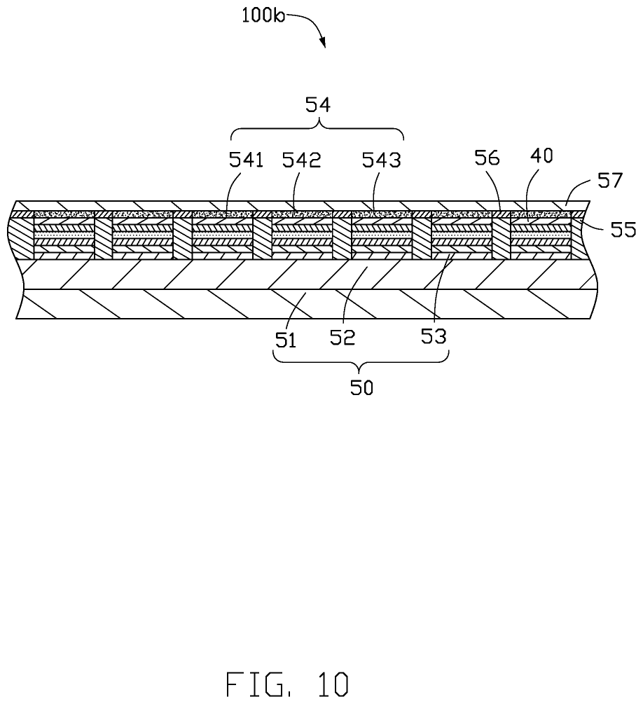

In one embodiment, all the crystal blocks 30 are patterned to form light emitting elements 40 emitting light of one color (e.g., blue light). The driving substrate 50 defines a plurality of sub-pixels (not shown), such as red pixels R, green pixels and blue pixels B. As shown in FIG. 10, after forming the insulating block 55 between adjacent light emitting elements 40, the method further includes forming a wavelength conversion block 54 on a side of each of the light emitting elements 40 away from the conductive block 53, and forming a black matrix 56 between adjacent wavelength conversion blocks 54. A cover 57 is formed on a side of the light emitting element 40 away from the driving substrate 50. Thereby, a display panel 100b is obtained. The adjacent light emitting elements 40 are insulated by one of the insulating blocks 55. The cover 57 seals and protects the driving circuit layer 52 and the light emitting element 40.

In an embodiment, the wavelength conversion blocks 54 are made of quantum dots. For example, each of the light emitting elements 40 is a diode emitting blue light. The wavelength conversion blocks 54 include first wavelength conversion blocks 541, second wavelength conversion blocks 542, and third wavelength conversion blocks 543, which may be quantum dots respectively outputting red color, green color, and blue color. The blue light emitted by the light emitting elements 40 undergoes wavelength conversion to realize color display of the display panel 100b.

In other embodiments, the material of the wavelength conversion blocks 54 is a photoresist. For example, each of the light emitting elements 40 is a diode emitting blue light. The wavelength conversion blocks 54 include first wavelength conversion blocks 541, second wavelength conversion blocks 542, and third wavelength conversion blocks 543, which apply a photoresist respectively for red, green, and blue colors. The blue light emitted by the light emitting elements 40 undergoes wavelength conversion to realize color display of the display panel 100b.

In the method for making the display panel, after the crystal blocks 30 are transferred to the driving substrate 50, each of the crystal blocks 30 is patterned to form a plurality of light emitting elements 40. That is, one operation of alignment of the crystal blocks 30 and the receiving areas 50a on the driving substrate 50 realizes the transfer a large number of light emitting elements 40 onto the driving substrate 50. Compared with the method of one-to-one alignment and transfer of a large number of very small light emitting elements 40 and the conductive blocks 53 on the driving substrate 50 one by one, the number of alignments is greatly reduced. The manufacturing process is simplified, and the manufacturing time is greatly shortened. In addition, since the number of alignments is reduced, the yield of en masse transfers is improved.

It is to be understood, even though information and advantages of the present exemplary embodiments have been set forth in the foregoing description, together with details of the structures and functions of the present exemplary embodiments, the disclosure is illustrative only. Changes may be made in detail, especially in matters of shape, size, and arrangement of parts within the principles of the present exemplary embodiments to the full extent indicated by the plain meaning of the terms in which the appended claims are expressed.

What is claimed is:

1. A method for making a display panel, comprising:
providing a plurality of crystal blocks;
providing a driving substrate, wherein the driving substrate defines a plurality of receiving areas, each of the plurality of receiving areas defines a plurality of conductive blocks spaced apart from each other, and each of the plurality of receiving areas is configured for receiving one of the plurality of crystal blocks;
transferring the plurality of crystal blocks to the driving substrate, wherein each of the plurality of crystal blocks is transferred to a corresponding one of the plurality of receiving areas; and
patterning the plurality of crystal blocks, wherein each of the plurality of crystal blocks is patterned to form a plurality of light emitting elements spaced apart from each other, each of the plurality of light emitting elements is on one of the plurality of conductive blocks and is electrically connected to the one of the plurality of conductive blocks.

2. The method for making the display panel according to claim 1, wherein providing the plurality of crystal blocks comprises:
providing a substrate;
forming a release layer on the substrate; and
forming the plurality of crystal blocks spaced from each other on a surface of the release layer away from the substrate, wherein each of the plurality of crystal blocks comprises a first electrode layer, a P-type doped phosphor layer, an active layer, an N-type doped phosphor layer and a second electrode layer arranged in said sequence.

3. The method for making the display panel according to claim 2, further comprising treating the release layer, so that each of the plurality of crystal blocks is detached from the substrate and is transferred to the driving substrate.

4. The method for making the display panel according to claim 2, wherein transferring the plurality of crystal blocks to the driving substrate comprises making the first electrode layer of each of the plurality of crystal blocks covering all of the plurality of conductive blocks in the corresponding one of the plurality of receiving areas.

5. The method for making the display panel according to claim 4, wherein patterning the plurality of crystal blocks comprises patterning the first electrode layer, the P-type doped phosphor layer, the active layer, the N-type doped phosphor layer, and the second electrode.

6. The method for making the display panel according to claim 1, wherein the plurality of light emitting elements formed by patterning the same crystal block emits light of one color; the plurality of light emitting elements formed by patterning different ones of the plurality of crystal blocks emits light of one color or different colors.

7. The method for making the display panel according to claim 1, wherein the plurality of light emitting elements formed by patterning the plurality of crystal blocks all emits light of one color.

8. The method for making the display panel according to claim 7, further comprising forming a wavelength conversion block on a side of each of the plurality of light emitting elements away from the one of the plurality of conductive blocks.

9. The method for making the display panel according to claim 8, further comprising forming a black matrix between adjacent wavelength conversion blocks.

10. The method for making the display panel according to claim 9, wherein a material of the wavelength conversion block is quantum dots.

11. The method for making the display panel according to claim 9, wherein a material of the wavelength conversion block is photoresist.

12. The method for making the display panel according to claim 9, wherein each of the plurality of light emitting elements is a diode emitting blue light, the blue light emitted by each of the plurality of light emitting elements undergoes wavelength conversion to realize color display of the display panel.

13. The method for making the display panel according to claim 1, further comprising forming an insulating block between adjacent ones of the plurality of light emitting elements.

14. The method for making the display panel according to claim 1, further comprising forming a cover on a side of the plurality of light emitting elements away from the driving substrate.

15. The method for making the display panel according to claim 1, wherein providing the driving substrate comprises providing a base layer, forming a driving circuit layer on a side of the base layer, and forming the plurality of conductive blocks on a side of the driving circuit layer away from the base layer; each of the plurality of conductive blocks is electrically connected to the driving circuit layer.
